(19) United States
(12) Patent Application Publication
(10) Pub. No.: US 2026/0133496 A1
(43) Pub. Date: May 14, 2026

(54) LITHOGRAPHY MASKS INCLUDING CURVILINEAR SUB-RESOLUTION ASSIST FEATURES AND METHOD OF MANUFACTURING THEREOF

(71) Applicant: Taiwan Semiconductor Manufacturing Company, Ltd., Hsinchu (TW)

(72) Inventors: Che-Yuan CHANG, Hsinchu (TW); Yung Seng PANG, Hsinchu (TW); Si Tong LIU, Hsinchu (TW); Chi-Ta LU, Hsinchu (TW); Yin-Chuan CHEN, Hsinchu (TW)

(73) Assignee: Taiwan Semiconductor Manufacturing Company, Ltd., Hsinchu (TW)

(21) Appl. No.: 18/941,915

(22) Filed: Nov. 8, 2024

(51) Int. Cl. G03F 7/00; G03F 1/22; G03F 1/26

(52) U.S. Cl. CPC G03F 7/70008; G03F 1/22; G03F 1/26; G03F 7/0005

(57) ABSTRACT

A method of fabricating a lithography mask includes receiving a target aerial image for a lithographic process; performing a computational inverse lithography transformation on the target aerial image to generate an inverse aerial image; generating an inverse aerial image gradient by determining differences between two or more inverse aerial images computed at respective different focal distances; determining an image log slope based on the inverse aerial image; forming a weighted sum of the inverse aerial image, the inverse aerial image gradient, and the image log slope; and determining primary mask features and curved sub-resolution assist features that correspond to a spatial distribution of intensities of the weighted sum that exceed a first predetermined threshold. The method further includes performing an iterative optimization based on a gradient of a cost function to optimize a lithography mask layout such that the lithography mask generates an aerial image having improved depth of focus.

### BACKGROUND

Integrated circuit (IC) design becomes more challenging as IC technologies continually progress towards smaller feature sizes, such as 32 nm, 28 nm, 20 nm, and below. For example, when fabricating IC devices, IC device performance is seriously influenced by lithography printability capability, which indicates how well a final wafer pattern formed on a wafer corresponds with a target pattern defined by an IC design layout. Various methods that focus on optimizing a mask used for projecting an image that corresponds with the target pattern on the wafer have been introduced for enhancing lithography printability, such as optical proximity correction (OPC), mask proximity correction (MPC), inverse lithography technology (ILT), and source mask optimization (SMO). Although such methods have provided improvements to mask technology, many challenges remain.

### BRIEF DESCRIPTION OF THE DRAWINGS

The present disclosure is best understood from the following detailed description when read with the accompanying figures. It is emphasized that, per the standard practice in the industry, various features are not drawn to scale and are used for illustration purposes only. The dimensions of the various features may be arbitrarily increased or reduced for clarity of discussion.

FIG. 1 is a simplified block diagram of an integrated circuit (IC) manufacturing system, along with an IC manufacturing flow associated with the IC manufacturing system, according to various embodiments.

FIG. 2 is a simplified block diagram of an optical lithography system, which can be implemented by the IC manufacturing system of FIG. 1, according to various embodiments.

FIG. 3 is a simplified schematic illustrating an OPC-based computational lithography process, which can be implemented by the IC manufacturing system of FIG. 1 according to various aspects of the present disclosure.

FIG. 4A is an example target areal image for a lithographic process exposure according to various embodiments.

FIG. 4B is an example initial mask layout including primary mask features and sub-resolution assist features according to various embodiments.

FIG. 4C is a mask layout including primary mask features and curved sub-resolution assist features according to various embodiments.

FIG. 4D is a depth-of-focus plot for the initial mask layout of FIG. 4B according to various embodiments.

FIG. 4E is a depth-of-focus plot for the initial mask layout of FIG. 4B according to various embodiments.

FIG. 5 is a flowchart illustrating various processes in a computational lithography process that generates a mask layout according to various embodiments.

FIG. 6A is an example of an initial mask layout generated by the computational lithography process of FIG. 5 according to various embodiments.

FIG. 6B is an example of an updated mask layout generated by the computational lithography process of FIG. 5 after five iterations according to various embodiments.

FIG. 6C is an example of an updated mask layout generated by the computational lithography process of FIG. 5 after N iterations according to various embodiments.

FIG. 7A is an example initial mask layout including primary mask features and sub-resolution assist features according to various embodiments.

FIG. 7B is a further mask layout including primary mask features and curved sub-resolution assist features according to various embodiments.

FIG. 7C is a depth-of-focus plot that compares the initial mask layout of FIG. 7A to the mask layout of FIG. 7B according to various embodiments.

FIG. 8 is a flowchart illustrating operations of a method of fabricating a lithography mask according to various embodiments.

FIG. 9 is a flowchart illustrating operations of a further method of fabricating a lithography mask according to various embodiments.

FIG. 10A illustrates an apparatus for performing the methods of FIGS. 8 and 9, according to various embodiments.

FIG. 10B is a schematic layout of components of the apparatus of FIG. 10A, according to various embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous by providing a method of fabricating a lithography mask based on a computational lithography process that optimizes the lithography mask to have improved resolution, depth of focus, or other metrics. For example, the topography effect caused by high-level metal layers is also improved in various embodiments. The resulting lithography mask includes primary mask features and curved sub-resolution assist features that satisfy various constraints of mask printability, depth of focus of an aerial image generated by the lithography mask, and design constraints of the aerial image. The method includes performing an iterative optimization algorithm based on a gradient of a cost function that is based on one or more metrics including differences between a projected aerial image and a target image, a defocused image gradient, and an image log slope of the projected aerial image.

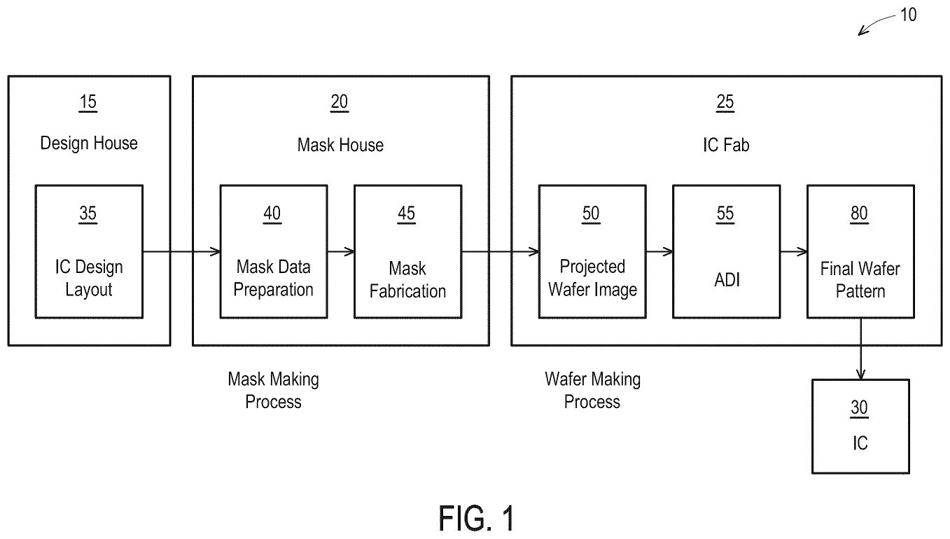

FIG. 1 is a simplified block diagram of an integrated circuit (IC) manufacturing system 10, along with an IC manufacturing flow associated with the IC manufacturing system 10, according to various embodiments. The IC manufacturing system 10 includes a plurality of entities, such as a design house (or design team) 15, a mask house 20, and an IC manufacturer 25 (for example, an IC fab), that interact with one another in design, development, and manufacturing cycles and/or services related to manufacturing an IC device 30. The plurality of entities is connected by a communication network, which may be a single network or a variety of different networks, such as an intranet and/or the Internet, and include wired and/or wireless communication channels. Each entity may interact with other entities and may provide services to and/or receive services from the other entities. One or more of the design house 15, the mask house 20, and the IC manufacturer 25 may be owned by a single large company, and may even coexist in a common facility and use common resources.

The design house 15 generates an IC design layout 35 (also referred to as an IC design pattern). The IC design layout 35 includes various circuit patterns (represented by geometrical shapes) designed for an IC product based on specifications of an IC product to be manufactured. The circuit patterns correspond to geometrical patterns formed in various material layers (such as metal layers, dielectric layers, and/or semiconductor layers) that combine to form IC features (components) of the IC product, such as the IC device 30. For example, a portion of the IC design layout 35 includes various IC features to be formed in a substrate (for example, a silicon substrate) and/or in various material layers disposed on the substrate. The various IC features include an active region, a gate feature (for example, a gate dielectric and/or a gate electrode), a source/drain feature, an interconnection feature, a bonding pad feature, other IC features, or combinations thereof. In some implementations, assist features are inserted into the IC design layout 35 to provide imaging effects, process enhancements, and/or identification information.

A geometry proximity correction (GPC) process, similar to an optical proximity correction (OPC) process used for optimizing mask patterns (mask layouts), may generate the assist features based on environmental impacts associated with IC fabrication, including etching loading effects, patterning loading effects, and/or chemical mechanical polishing (CMP) process effects. The design house 15 implements a design procedure to form the IC design layout 35. The design procedure include logic design, physical design, placement and routing, or combinations thereof. The IC design layout 35 is presented in one or more data files that include information of the circuit patterns (geometrical patterns).

The mask house 20 uses the IC design layout 35 to manufacture one or more masks, which are used for fabricating various layers of the IC device 30 according to the IC design layout 35. A mask (also referred to as a photomask or reticle) refers to a patterned substrate used in a lithography process to pattern a wafer, such as a semiconductor wafer. The mask house 20 performs mask data preparation 40, where the IC design layout 35 is translated into a form that can be written by a mask writer to generate a mask. For example, the IC design layout 35 is translated into machine readable instructions for a mask writer. Mask data preparation 40 generates a mask pattern (mask layout) that corresponds with a target pattern defined by the design layout 35. The mask pattern is generated by fracturing the target pattern of the IC design layout 35 into a plurality of mask features (mask regions) suitable for a mask making lithography process. The fracturing process is implemented according to various factors, such as IC feature geometry, pattern density differences, and/or critical dimension (CD) differences, and the mask features are defined based on methods implemented by the mask writer for printing mask patterns. In some implementations, a mask pattern is generated by fracturing the IC design layout 35 into polygons (such as rectangles or trapezoids), where exposure information is generated for each polygon. Exposure information can define an exposure dose, an exposure time, and/or an exposure shape, for each polygon. As described in detail below, mask data preparation 40 can implement various processes for optimizing the mask pattern, such that a final pattern formed on a wafer (often referred to as a final wafer pattern) by a lithography process using a mask fabricated from the mask pattern exhibits enhanced resolution and precision.

The mask house 20 also performs mask fabrication 45, where a mask is fabricated according to the mask pattern generated by mask data preparation 40. In some implementations, the mask pattern is modified during mask fabrication 45 to comply with a particular mask writer and/or mask manufacturer. During mask fabrication 45, a mask making process is implemented that fabricates a mask based on the mask pattern (mask layout). The mask includes a mask substrate and a patterned mask layer, where the patterned mask layer includes a final (real) mask pattern.

The final mask pattern, such as a mask contour, corresponds with the mask pattern (which corresponds with the target pattern provided by the IC design layout 35). In some implementations, the mask is a binary mask. In such implementations, according to one example, an opaque material layer (such as chromium) is formed over a transparent mask substrate (such as a fused quartz substrate or calcium fluoride (CaF₂)), and the opaque material layer is patterned based on the mask pattern to form a mask having opaque regions and transparent regions. In some implementations, the mask is a phase shift mask (PSM) that can enhance imaging resolution and quality, such as an attenuated PSM or alternating PSM. In such implementations, according to one example, a phase shifting material layer (such as molybdenum silicide (MoSi) or silicon oxide (SiO₂)) is formed over a transparent mask substrate (such as a fused quartz substrate or calcium fluoride (CaF₂)), and the phase shifting material layer is patterned to form a mask having partially transmitting, phase shifting regions and transmitting regions that form the mask pattern.

In another example embodiment, the phase shifting material layer is a portion of the transparent mask substrate, such that the mask pattern is formed in the transparent mask substrate. In some implementations, the mask is an extreme ultraviolet (EUV) mask. In such implementations, according to one example, a reflective layer is formed over a substrate, an absorption layer is formed over the reflective layer, and the absorption layer (such as a tantalum boron nitride (TaBN)) is patterned to form a mask having reflective regions that form the mask pattern. The substrate includes a low thermal expansion material (LTEM), such as fused quartz, TiO₂ doped SiO₂, or other suitable low thermal expansion materials. The reflective layer can include multiple layers formed on the substrate, where the multiple layers include a plurality of film pairs, such as molybdenum-silicon (Mo/Si) film pairs, molybdenum-beryllium (Mo/Be) film pairs, or other suitable material film pairs configured for reflecting EUV radiation (light). The EUV mask may further include a capping layer (such as ruthenium (Ru)) disposed between the reflective layer and the absorption layer. Alternatively, another reflective layer is formed over the reflective layer and patterned to form an EUV phase shift mask.

Mask fabrication 45 can implement various lithography processes for fabricating the mask. For example, the mask making process includes a lithography process, which involves forming a patterned energy-sensitive resist layer on a mask material layer and transferring a pattern defined in the patterned resist layer to the mask patterning layer. The mask material layer is an absorption layer, a phase shifting material layer, an opaque material layer, a portion of a mask substrate, and/or other suitable mask material layer. In some implementations, forming the patterned energy-sensitive resist layer includes forming an energy-sensitive resist layer on the mask material layer (for example, by a spin coating process), performing a charged particle beam exposure process, and performing a developing process. The charged particle beam exposure process directly “writes” a pattern into the energy-sensitive resist layer using a charged particle beam, such as an electron beam or an ion beam. Since the energy-sensitive resist layer is sensitive to charged particle beams, exposed portions of the energy-sensitive resist layer chemically change, and exposed (or non-exposed) portions of the energy-sensitive resist layer are dissolved during the developing process depending on characteristics of the energy-sensitive resist layer and characteristics of a developing solution used in the developing process.

After development, the patterned resist layer includes a resist pattern that corresponds with the mask pattern. The resist pattern is then transferred to the mask material layer by any suitable process, such that a final mask pattern is formed in the mask material layer. For example, the mask making process can include performing an etching process that removes portions of the mask material layer, where the etching process uses the patterned energy-sensitive resist layer as an etch mask during the etching process. After the etching process, the lithography process can include removing the patterned energy-sensitive resist layer from the mask material layer, for example, by a resist stripping process.

The IC manufacturer 25, such as a semiconductor foundry, uses the mask (or masks) fabricated by mask house 20 to fabricate the IC device 30. For example, a wafer making process is implemented that uses a mask to fabricate a portion of the IC device 30 on a wafer, such as a semiconductor wafer. In some implementations, IC manufacturer 25 performs wafer making processes numerous times using various masks to complete fabrication of the IC device 30. Depending on the IC fabrication stage, the wafer can include various material layers and/or IC features (for example, doped features, gate features, and/or interconnect features) when undergoing the wafer making process. The wafer making process includes a lithography process, which involves forming a patterned resist layer on a wafer material layer using a mask, such as the mask fabricated by mask house 20, and transferring a pattern defined in the patterned resist layer to the wafer material layer. The wafer material layer is a dielectric layer, a semiconductor layer, a conductive layer, a portion of a substrate, and/or other suitable wafer material layer.

Forming the patterned resist layer can include forming a resist layer on the wafer material layer (for example, by spin coating), performing a pre-exposure baking process, performing an exposure process using the mask (including mask alignment), performing a post exposure baking process, and performing a developing process. During the exposure process, the resist layer is exposed to radiation energy (such as ultraviolet (UV) light, deep UV (DUV) light, or extreme UV (EUV) light) using an illumination source, where the mask blocks, transmits, and/or reflects radiation to the resist layer depending on a final mask pattern of the mask and/or mask type (for example, binary mask, phase shift mask, or EUV mask), such that an image is projected onto the resist layer that corresponds with the final mask pattern. This image is referred to herein as a projected wafer image 50. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the final mask pattern. An after-development inspection (ADI) 55 can be performed to capture information associated with the resist pattern, such as critical dimension uniformity (CDU) information, overlay information, and/or defect information.

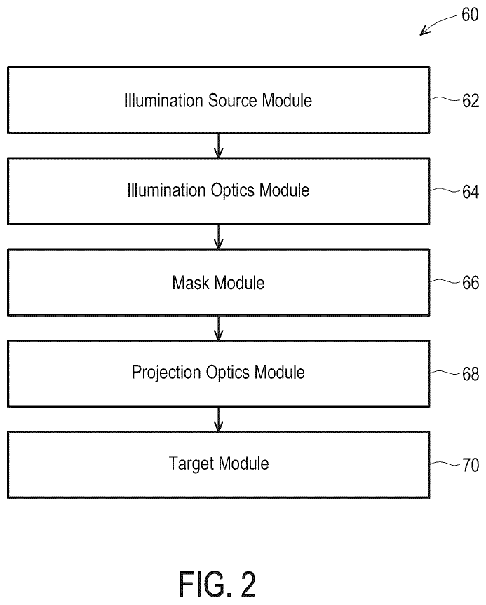

FIG. 2 is a simplified block diagram of an optical lithography system 60 for imaging a pattern of a mask onto a workpiece, which can be implemented by the IC fab 25, according to various embodiment. The workpiece includes a wafer, a mask, or any base material on which processing is conducted to produce layers of material configured to form IC patterns and/or IC features. In some implementations, the workpiece is a wafer having a radiation sensitive layer (for example, a resist layer) disposed thereover. In FIG. 2, optical lithography system 60 includes an illumination source module 62, an illumination optics module 64, a mask module 66, projection optics module 68, and a target module 70.

Illumination source module 62 includes a radiation source that generates and emits radiation (light) of a suitable wavelength, such as UV radiation, DUV radiation, EUV radiation, other suitable radiation, or a combination thereof. Illumination optics module 64 collects, guides, and directs the radiation, such that the radiation is projected onto a mask. Mask module 66 includes a mask stage for holding the mask and manipulating a position of the mask. The mask transmits, absorbs, and/or reflects the radiation depending on a final mask pattern of the mask, along with mask technologies used to fabricate the mask, thereby projecting patterned radiation.

The projection optics module 68 collects, guides, and directs the patterned radiation from the mask module 66 to a workpiece of the target module 70, such that an image of the mask (corresponding with the final mask pattern) is projected onto the workpiece. The target module 70 can include a wafer stage for holding the workpiece and manipulating a position of the workpiece. In some implementations, the target module 70 provides control of a position of the workpiece, such that an image of the mask can be scanned onto the workpiece in a repetitive fashion (though other scanning methods are possible). In some implementations, the illumination optics module 64 includes various optical components for collecting, directing, and shaping the radiation onto the mask, and projection optics module 68 includes various optical components for collecting, directing, and shaping the patterned radiation onto the workpiece. Such optical components include refractive components, reflective components, magnetic components, electromagnetic components, electrostatic components, and/or other types of components for collecting, directing, and shaping the radiation. FIG. 2 is simplified for the sake of clarity to better understand the inventive concepts of the present disclosure. Additional features can be added in optical lithography system 60, and some of the features described below can be replaced, modified, or eliminated for additional embodiments of optical lithography system 60.

The wafer making process implemented by the IC manufacturer 25 (see FIG. 1), including transferring the resist pattern defined in the patterned resist layer to the wafer material layer is accomplished in numerous ways, such that a final wafer pattern 80 is formed in the wafer material layer. For example, the wafer making process can include performing an implantation process to form various doped regions/features in the wafer material layer, where the patterned resist layer is used as an implantation mask during the implantation process. In another example, the wafer making process includes performing an etching process that removes portions of the wafer material layer, where the etching process uses the patterned resist layer as an etch mask during the etching process.

After the implantation process or the etching process, the lithography process includes removing the patterned resist layer from the wafer, for example, by a resist stripping process. In yet another example, the wafer making process includes performing a deposition process that fills openings in the patterned resist layer (formed by the removed portions of the resist layer) with a dielectric material, a semiconductor material, or a conductive material. In such implementations, removing the patterned resist layer leaves a wafer material layer that is patterned with a negative image of the patterned resist layer. An after etch inspection (AEI) can be performed to capture information, such as CDU, associated with the final wafer pattern 80 formed in the wafer material layer.

Ideally, the final wafer pattern 80 matches the target pattern defined by the IC design layout 35. However, due to various factors associated with the mask making process and the wafer making process, the final mask pattern formed on the mask often varies from the mask pattern (generated from the target pattern defined by the IC design layout 35), causing the final wafer pattern 80 formed on the wafer to vary from the target pattern. For example, mask writing blur (such as e beam writing blur) and/or other mask making factors cause variances between the final mask pattern and the mask pattern, which causes variances between the final wafer pattern 80 and the target pattern. Various factors associated with the wafer making process (such as resist blur, mask diffraction, projection imaging resolution, acid diffusion, etching bias, and/or other wafer making factors) further exacerbate the variances between final wafer pattern 80 and the target pattern.

Computational lithography has been introduced for enhancing and optimizing the mask masking process and the wafer making process, thereby minimizing variances between the final wafer pattern 80 and the target pattern. Computational lithography generally refers to any technique implementing computationally-intensive physical models and/or empirical models to predict and optimize IC feature patterning, where the physical models and/or the empirical models are based on phenomena that affect lithographic process results, such as imaging effects (for example, diffraction and/or interference) and/or resist chemistry. The IC manufacturing system 10 can implement such techniques to generate optimal settings for the illumination optics module 64 (often referred to as source optimization), the mask module 66 (often referred to as mask optimization), the projection optics module 68 (often referred to as wave front engineering), and/or the target module 70 (often referred to as target optimization).

For example, the IC manufacturing system 10 can implement source mask optimization (SMO) to generate a shape for a final mask pattern of a mask (fabricated by the mask house 20) and a shape of radiation for exposing the mask (provided by the illumination optics module 64) that optimizes the projected wafer image 50. In another example, the IC manufacturing system 10 can implement wavefront engineering to generate settings for the projection optics module 68 that optimize the projected wafer image 50. In yet another example, the IC manufacturing system 10 can implement optical proximity correction (OPC), mask rule check (MRC), lithographic process check (LPC), and/or inverse lithography technology (ILT) techniques to generate a shape for a final mask pattern of a mask (fabricated by the mask house 20) that optimizes the projected wafer image 50.

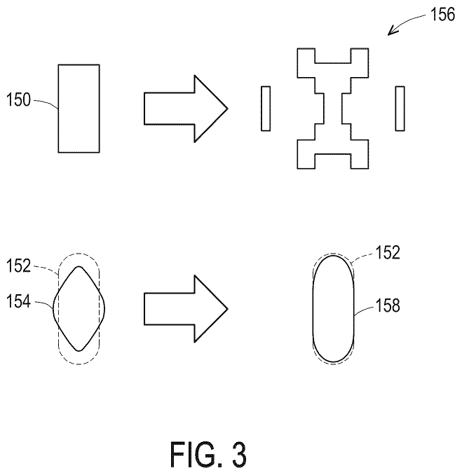

FIG. 3 is a simplified schematic illustrating an OPC-based computational lithography process, which can be performed at the mask data preparation 40, according to various embodiments. For example, a target pattern includes a target feature 150 to be formed on a wafer. A target contour 152 defines a shape of a pattern printed (imaged) on the wafer by exposing a mask that includes the target feature 150 given ideal lithographic process conditions. Even with ideal lithographic process conditions, lithography constraints prevent the target feature 150 from being printed on the wafer with corners formed by right angles, such that the target contour 152 exhibits rounded comers. A predicted contour 154 represents a pattern printed on the wafer by exposing the mask that includes the target feature 150 given predicted lithographic process conditions. In some implementations, the mask data preparation 40 can implement a LPC process to generate the predicted contour 154. The LPC process simulates an image of a mask based on a generated mask pattern using various LPC models (or rules), which may be derived from actual (historic) processing data associated with the IC fab 25 fabricating IC devices. The processing data can include processing conditions associated with various processes of the IC manufacturing cycle, conditions associated with tools used for manufacturing the IC, and/or other aspects of the manufacturing process. The LPC process considers various factors, such as image contrast, depth of focus, mask error sensitivity, other suitable factors, or combinations thereof.

As depicted in FIG. 3, since the predicted contour 154 varies from the target contour 152, OPC is performed to modify the target pattern until a predicted contour fits the target contour 152, thereby generating an OPC-modified target pattern. For example, a target feature 150 is transformed into an OPC-modified target feature 156 to compensate for lithographic process conditions that cause such variances, such that a predicted contour 158 is generated that fits the target contour 152, significantly improving lithography printability. The predicted contour 158 represents a pattern printed on the wafer by exposing a mask that includes the OPC-modified target feature 156 given predicted lithographic process conditions. In some implementations, an LPC process generates the predicted contour 158.

OPC uses lithography enhancement techniques to compensate for image distortions and errors, such as those that arise from diffraction, interference, or other process effects. OPC can add assist features (AFs), such as scattering bars, serifs, and/or hammerheads, to the target pattern (here, target feature 150) or modify (such as resize, reshape, and/or reposition) the target pattern according to optical models (referred to as model-based OPC) and/or optical rules (referred to as rule-based OPC), such that after a lithography process, a final wafer pattern exhibits enhanced resolution and precision. In some implementations, OPC distorts the target pattern to balance image intensity, for example, removing portions of the target pattern to reduce over-exposed regions and adding AFs to the target pattern to enhance under-exposed regions. In some implementations, AFs compensate for line width differences that arise from different densities of surrounding geometries. In some implementations, AFs can prevent line-end shortening and/or line-end rounding. OPC can further correct fore-beam proximity effects and/or perform other optimization features.

In some implementations, the OPC process and the LPC process are iterative processes, where multiple iterations (for example, modifications and simulations) are performed to generate an OPC-modified target feature 156. In some implementations, the target contour 152 is represented by a plurality of target points generated by an OPC process along a perimeter the defining target feature 150 (here, target contour 152), and the predicted contour 154 represents a perimeter defining the target feature 150 generated by an LPC process. In such implementations, a dissection process may be performed on the target contour 152, where the target contour 152 is dissected into multiple discrete segments defined by a plurality of dissection points (also referred to as stitching points). Each segment is a portion of the target contour 152 defined between adjacent dissection points. Then, at least one target point may be assigned to each segment, such that target points are spaced at locations along the target contour 152.

In some implementations, the OPC process modifies the target feature 150 until distances between target points of the target contour 152 and a predicted contour fall within an acceptable distance range. In some implementations, the mask data preparation 40 further implements an MRC process that checks the mask pattern after undergoing OPC, where the MRC process uses a set of mask creation rules. The mask creation rules can define geometric restrictions and/or connectivity restrictions to avoid various issues and/or failures that can arise from variations in IC manufacturing processes. FIG. 3 is simplified for the sake of clarity. Additional features can be added in the OPC-based computational lithography process, and some of the features described below can be replaced, modified, or eliminated for additional embodiments of the OPC-based computational lithography process.

OPC-based computational lithography techniques and computational lithography techniques aim to minimize a cost function that defines a variance between a predicted contour and a target contour, such as an edge placement error (EPE). The cost function can further correlate such variance with various penalties arising from process constraints related to the lithography process, such as an MRC penalty and/or an AF printing penalty. Though an optimized target pattern that exhibits a predicted contour with minimal variance from the target contour can be generated by such techniques, a shape of the target contour can negatively influence process windows. For example, obtaining a target contour with sharp corners under nominal conditions results in low contrast and/or low depth of focus. However, not every segment of a target contour has a distinct target. For example, a shape of the target contour can be varied (for example, to have rounded corners instead of sharp corners), yet still achieve desired functionality of the target pattern.

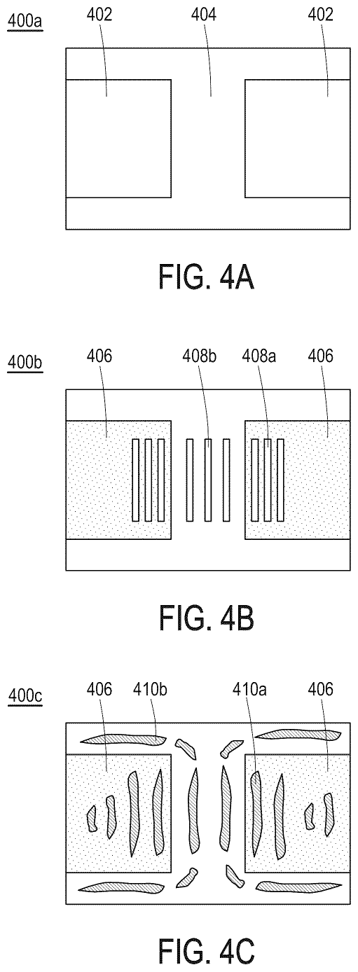

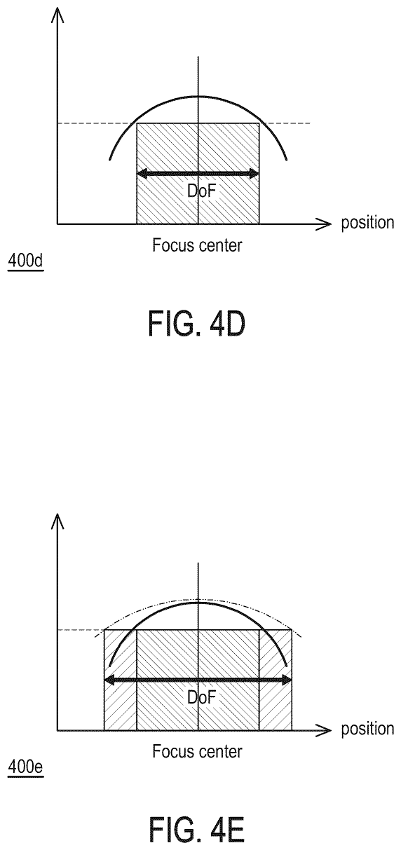

FIG. 4A is an example target aerial image 400a for a lithographic process exposure, and FIG. 4B is an example initial mask layout 400b including primary mask features 406 and sub-resolution assist features (408a, 408b). As shown in FIG. 4A, the target aerial image 400a includes exposure areas 402 and non-exposure areas 404. The initial mask layout 400b includes primary mask features 406 corresponding to the exposure areas 402. If the initial mask layout 400b is configured as a transmissive mask, the primary mask features 406 are transmissive features, and if the initial mask layout 400b is configured as a reflective mask, the primary mask features 406 are configured as reflective features. The sub-resolution assist features 408 may be defined using rule-based or model-based OPC techniques, as described above. As shown in FIG. 4B, the sub-resolution assist features 408 include a first sub-resolution assist feature 408a and a second sub-resolution assist feature 408b. In embodiments in which the primary mask features 406 are transmissive/reflective, the first sub-resolution assist feature 408a may be non-transmissive (e.g., absorbing) and the second sub-resolution assist feature 408b may be transmissive/reflective.

FIG. 4C is a mask layout 400c including primary mask features 406 and curved sub-resolution assist features (410a, 410b), according to various embodiments. As shown in FIG. 4C, the curved sub-resolution assist features (410a, 410b) include first curved sub-resolution assist features 410a and second curved sub-resolution assist features 410b. In embodiments in which the primary mask features 406 are transmissive/reflective, the first curved sub-resolution assist features 410a may be non-transmissive (e.g., absorbing) and the second sub-resolution assist feature 410b may be transmissive/reflective. The first curved sub-resolution assist features 410a are non-transmissive and therefore scatter or absorb radiation. As such, the curved sub-resolution assist features 410a are referred to as scattering bars (SB). Alternatively, the second curved sub-resolution assist features 410b are transmissive and represent areas where scattering or absorbing material is absent. As such, the second curved sub-resolution assist features 410b are referred to as hollow scattering bars (HSB).

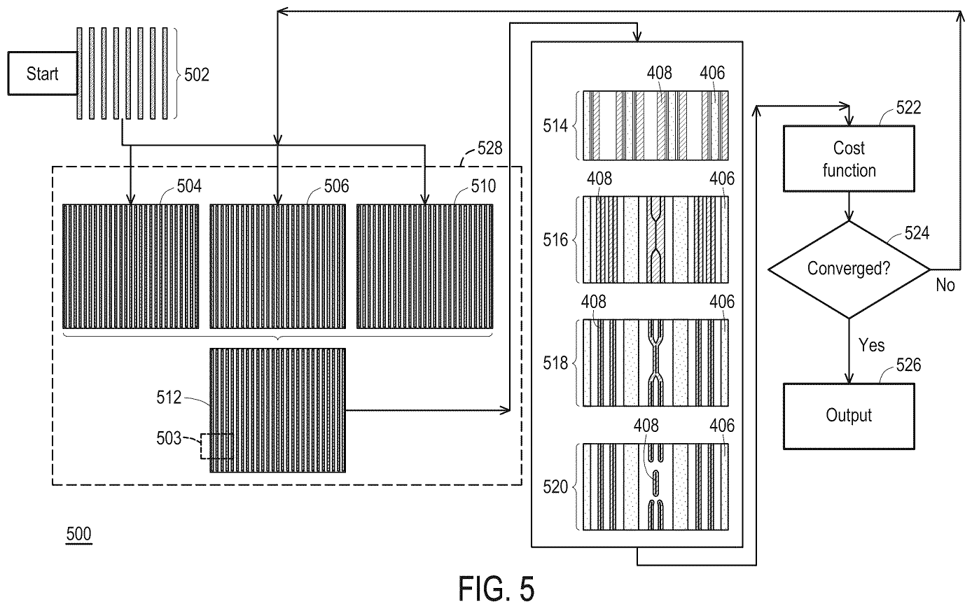

The use of curved sub-resolution assist features (410a, 410b) leads to improvement in optical resolution, depth of focus, and the topography effect of high-level metal layers. A calculational method is disclosed that determines the precise size and shape of the curved sub-resolution assist features (410a, 410b) by iteratively changing the size and shape of the curved sub-resolution assist features (410a, 410b) optimize one or more metrics. In this regard, the mask layout 400c is generated by a computational lithography process starting either from the target aerial image 400a of FIG. 4A or the initial mask layout 400b of FIG. 4B, as described in greater detail with reference to FIGS. 5 to 7C, below. According to various embodiments, the first curved sub-resolution assist features 410a and second curved sub-resolution assist features 410b have non-uniform widths. According to various embodiments, one or more curved sub-resolution assist features (410 a, 410 b) has a length that is greater than or equal to 250 nm. For example, one or more curved sub-resolution assist features (410 a, 410 b) has a length that is between 250 nm and 350 nm.

FIG. 4D is a depth-of-focus plot 400d for the initial mask layout of FIG. 4B, and FIG. 4E is a depth-of-focus plot 400e for the initial mask layout of FIG. 4C, according to various embodiments. The top curve in the depth-of-focus plot 400e of FIG. 4E corresponds to the mask layout 400c showing an increased depth of focus relative to the lower curve in depth-of-focus plot 400e, which represents the initial mask layout 400b of FIG. 4B. The mask layout 400c was generated by a computational lithography process that uses an iterative process that uses a cost function based on a defocused image such that the first curved sub-resolution assist features 410a and the second sub-resolution assist feature 410b are determined to minimize the cost function, leading to the improvement in the depth of focus. Various other metrics may be used to define the cost function to optimize the mask layout 400c with regard to other performance metrics, as described below in greater detail with reference to FIG. 5.

FIG. 5 is a flowchart illustrating various processes in a computational lithography process 500 that generates a mask layout 400c, according to various embodiments. As mentioned above, the computational lithography process 500 may be configured to start from a target aerial image (e.g., such as target aerial image 400a of FIG. 4A) or an initial mask layout (e.g., such as initial mask layout 400b of FIG. 4B). In the embodiment of FIG. 5, the computational lithography process 500 is assumed to start from a simple target aerial image 502. As shown in FIG. 5, the target aerial image 502 includes a plurality of parallel vertical features. The computational lithography process 500 performs a computational inverse lithography transformation on the target aerial image 502 to generate an inverse aerial image 504. The computational method is based on a grey level mask that is iteratively optimized as described below.

A grey level mask is a photomask used to control the intensity of light exposure during the photolithography process. Unlike traditional binary masks, which either completely block or allow light to pass through, grey level masks enable intermediate levels of light transmission by incorporating varying degrees of opacity. These masks typically use gradient-like patterns or microstructures to modulate the exposure dose across different regions of the substrate, allowing for more precise control over the photoresist development process. This technique is advantageous in applications requiring complex or multi-step topographies, such as 3D structures or finely tuned surface features, as it can achieve smoother transitions and higher resolution in the patterning of semiconductor devices. Example grey level masks include attenuated phase shift masks (APSM).

APSMs are a type of photomask that improves resolution and pattern fidelity by manipulating both the intensity and phase of the light used during exposure. Unlike conventional masks, APSMs incorporate materials that attenuate the light's intensity while shifting its phase by 180 degrees. This phase shift creates destructive interference at the edges of features, effectively sharpening the image of the pattern on the wafer. As a result, APSMs are particularly advantageous in producing finer patterns, enabling more precise control over feature dimensions and improving the overall resolution in advanced semiconductor fabrication processes. According to various embodiments, APSMs include phase shifts of 6%, 9%, 19%, or phase shifts between 5% to 30%. Other embodiments include binary phase-shift EUV masks.

The computational lithography process 500 then generates an inverse aerial image gradient 506 by determining differences between the inverse aerial image 504 computed by assuming the target aerial image 502 is at different focal distances. Also from the inverse aerial image 504, the computational lithography process 500 computes an image log slope 510 of the inverse aerial image 504, which is defined as the mapping of the spatial derivative of the logarithm of the intensity of the inverse aerial image: ∂(ln(I(r)))/∂r, where “r” is a two-dimensional coordinate (x, y) in the plane of the approximate aerial image. A first approximation mask layout 514 may then be determined by considering intensity variations of a weighted sum 512 of the inverse aerial image 504, the inverse aerial image gradient 506, and the image log slope 510. In this regard, primary mask features 406 and sub-resolution assist features 408 may be determined based on a spatial distribution of intensities of the weighted sum 512 that exceed a first predetermined threshold. The first approximation mask layout 514 is a magnified view of a portion 503 of the weighted sum 512. A second approximation mask layout 516, a third approximation mask layout 518, and a fourth approximation mask layout 520, described below, each have a similar magnification to that of the first approximation mask layout 514.

The primary mask features 406 and the curved sub-resolution assist features 410 may then be approximated as regular shapes (e.g., rectangles, polygons, etc.) as shown in a second approximation mask layout 516. Then, the placement of primary mask features 406 and curved sub-resolution assist features 410 may be checked against design rules, for example, to avoid features being placed too close together, being too small to be fabricated on a mask, etc. Then, based on the comparison with the design rules, one or more of the primary mask features and the curved sub-resolution assist features may be modified. For example, the modification operation includes decreasing a width of one or more of the primary mask features 406 and the sub-resolution assist features 408 to increase a relative separation of neighboring features; dividing one or more of the primary mask features 406 and the curved sub-resolution assist features by removing a portion of one or more of the primary mask features 406 and the sub-resolution assist features 408; and removing one or more of the primary mask features 406 and the sub-resolution assist features 408. The result of these modification operations can be seen in a third approximation mask layout 518 and a fourth approximation mask layout 520.

The computational lithography process 500 is performed as an iterative process to refine the primary mask features 406 and sub-resolution assist features 408 of a mask layout to optimize the mask layout according to one or more metrics. As such, a cost function 522 is defined and a convergence test 524 is performed at each iteration. Each iteration of the computational lithography process 500 generates a candidate-modified mask layout (e.g., the fourth approximation mask layout 520). Based on the convergence test 524 the candidate-modified mask layout may lead either to an improved mask layout in which the cost function 522 is reduced from a previous iteration or a degraded mask layout in which the cost function 522 is increased from a previous iteration. In any given iteration, the computational lithography process 500 includes accepting the candidate modified-mask layout as an updated mask layout when the modified cost function is lower than the cost function in a previous iteration and rejecting the candidate modified-mask layout as the updated mask layout when the modified cost function is greater than the cost function in the previous iteration.

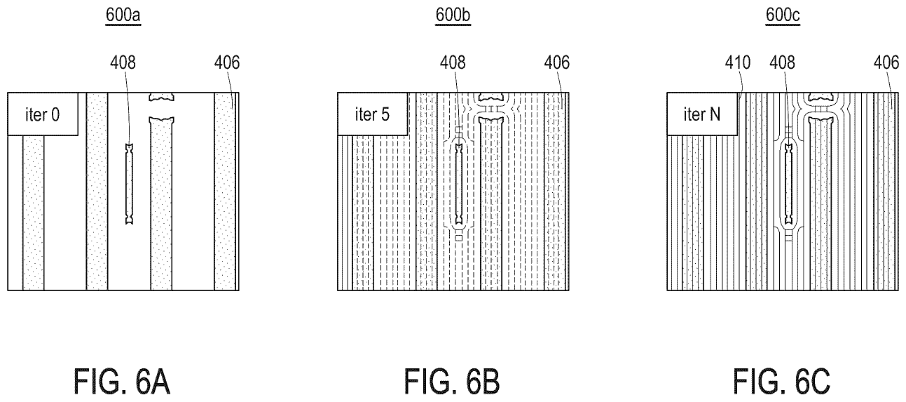

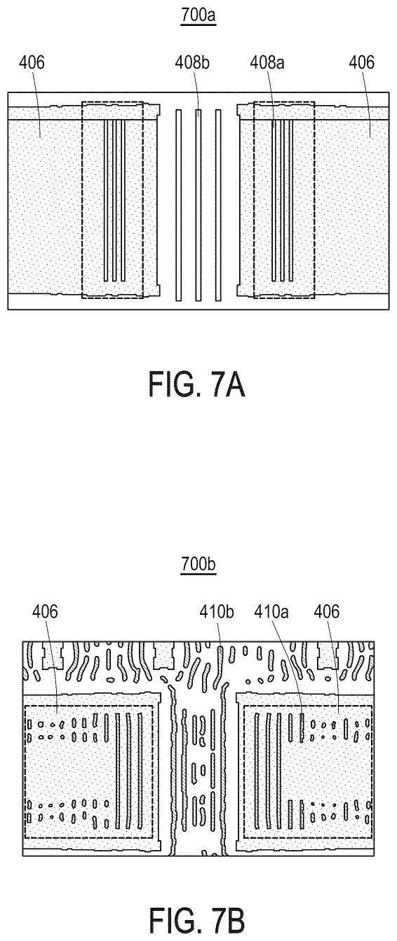

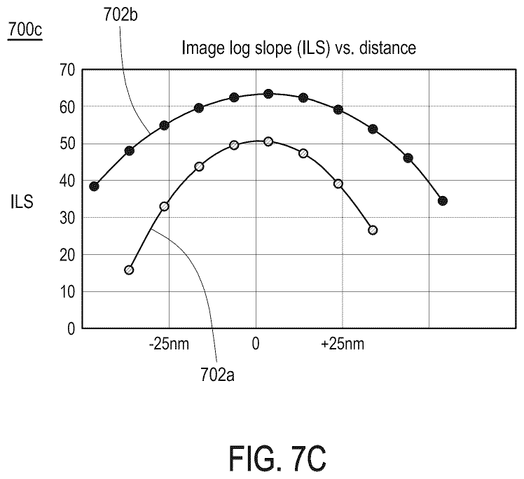

The computational lithography process 500 ends when either the convergence test 524 shows an affirmative result or a maximum number of iterations has been exceeded. When the computational lithography process 500 ends, an output mask layout 526 is provided. The output mask layout 526 is then used to fabricate a lithography mask (e.g., with mask layout 400c or 700b). In certain embodiments, the computational lithography process 500 may be based on a gradient optimization process in which only modifications that decrease the cost function are considered, as described in greater detail below. According to various embodiments, the computational lithography process 500 modifies the sub-resolution assist features 408 to generate curved sub-resolution assist features (410a, 410b) (e.g., see FIG. 4C), as described in greater detail below with reference to FIGS. 6A to 7C.

The cost function 522 may be defined in various ways depending on which properties of the mask layout (e.g., depth of focus, printability, similarity to the target aerial image, etc.) are to be optimized. For example, at any iteration, the current updated mask layout (e.g., the fourth approximation mask layout 520) is used to generate an approximate aerial image (not shown) in a lithography process (i.e., an aerial image generated by the updated mask layout). The approximate aerial image is then compared with the target aerial image 502 to determine differences between the target aerial image 502 and the approximate aerial image. The computational lithography process 500 may be performed to reduce differences between the approximate aerial image and the target aerial image 502 by defining the cost function 522 to depend on the differences between the target aerial image 502 and the approximate aerial image. For example, according to various embodiments, the cost function may be taken to be a sum of squares of the differences between the target aerial image 502 and the approximate aerial image at a plurality of points common to the approximate aerial image and the target aerial image 502. Various other cost functions 522 may be defined based on such differences in other embodiments.

In further embodiments, a cost function 522 may be based on a defocused image gradient. The defocused image gradient may be determined by computing aerial image differences between the approximate aerial image computed at two or more focal distances. As such, the cost function 522 may be defined to be a sum of squares of values of the defocused image gradient. Using such a cost function 522 causes the computational lithography process 500 to generate a mask layout having an improved depth of focus (e.g., see FIGS. 4C and 4E and related description, above).

In further embodiments, a cost function 522 is defined by determining an image log slope based on the approximate aerial image and defining the cost function 522 as a sum of squares of values of the image log slope (image: ∂(ln(I(r)))/∂r, where “r” is a two-dimensional coordinate (x, y) in the plane of the approximate aerial image). Using such a cost function 522 causes the computational lithography process 500 to generate a mask layout that reduces intensity gradients of the aerial image generated by the resulting mask layout. For example, as shown in FIG. 3, sharp corners of the target feature 150 are rounded to form the target contour 154.

It should be noted that the previously described image log slope 510 (e.g., see FIG. 5) was described in the context of the inverse aerial image, whereas in the current context, the image log slope (not shown) corresponds to an image log slope of the approximate aerial image (i.e., the aerial image generated by the current updated mask layout). This illustrates the complementary nature of the approximate aerial image and the inverse aerial image. In certain embodiments, these two quantities are Fourier transforms of one another under certain conditions. Thus, an image log slope may be applied to the approximate aerial image to smooth out corners in a pattern projected by the updated mask layout. Alternatively, the image log slope of the inverse log slope 510 generated from the inverse aerial image may be used to smooth out sharp features of the primary mask features 406 and the sub-resolution assist features 408. Indeed, this is one reason for defining the image log slope 510 when generating the first approximation mask layout 514 from the inverse aerial image.

Various other cost functions may be defined in corresponding embodiments. For example, in certain embodiments, a composite metric is defined to be a weighted sum of image differences, a defocused image gradient, and an image log slope. The cost function is then defined to be a sum of squares of the composite metric evaluated at a plurality of points at which intensities of the approximate aerial image are defined. These examples illustrate that different types of cost functions 522 may be defined based on what properties of the mask layout or the aerial image projected by the mask layout are to be optimized.

Each of the parameters in a weighted sum that defines the cost function 522 (based on the approximate aerial image) may be considered as parameters in the computational lithography process 500. As such, a gradient of the cost function with respect to these parameters may be defined. Alternatively, or in addition to these parameters, the parameters in the weighted sum 512 based on the inverse aerial image may also be considered as parameters of the cost function 522. Further, the features (406, 408) of the mask layout may be changed in various ways that may be parameterized. As such, the parameters used to describe shape changes (e.g., in terms of angles and magnitudes) may also be considered parameters on which a gradient of the cost function 522 may be defined.

A gradient of the cost function 522 may be a vector function of the cost function 522 based on derivatives of the cost function 522 with respect to the various parameters described above. By defining the gradient of the cost function 522, an interactive, gradient-based optimization algorithm may be performed to only introduce changes to the mask layout that reduce the cost function 522. As such, the computational lithography process 500 may be configured to have advantageous convergence properties. A constrained optimization of the cost function may also be performed in which certain parameters are held fixed during the iterative process. For example, the parameters defining the weighted sum in the cost function 522 may be held fixed. Similarly, the parameters in the weighted sum 512 based on the inverse aerial image may be held fixed.

FIG. 6A is an example of an initial mask layout 600a generated by the computational lithography process 500 of FIG. 5, and FIGS. 6B and 6C illustrate updated mask layouts (600b, 600 c) after 5 . . . N iterations, respectively, according to various embodiments. As shown in FIG. 6A, the initial mask layout 600a includes primary mask features 406 and at least one sub-resolution assist feature 408. In some embodiments, this initial mask layout 600a is generated based on an inverse areal image based on a target aerial image 502, as described above with reference to FIG. 5. Alternatively, in other embodiments, the initial mask layout 600a is generated based on an initial approximation for the mask layout (e.g., see initial mask layout 400b in FIG. 4B) based on design rules. As shown, for example, in FIGS. 6B to 6C, various curved sub-resolution assist features 410 develop as the computational lithography process 500 progresses.

As described above, the computational lithography process 500 may be based on a target aerial image 400a or based on an initial mask layout 400b. When starting from a target aerial image 400a (or initial mask layout 600a) the computational lithography process 500 proceeds by receiving a target areal image 502 for a lithographic process exposure, receiving an initial mask layout 400b including primary mask features 406 and one or more sub-resolution assist features 408, generating an approximate areal image (not shown) based on the initial mask layout 400b that includes the primary mask features 406 and the one or more sub-resolution assist features 408. The computational lithography process 500 then proceeds as described above but without operations 528 involving the inverse aerial image. For example, a cost function 522 is defined based on differences between the target aerial image and the approximate aerial image in some embodiments. Alternatively, the cost function 522 may be based on a defocused image gradient, an image log slope, or various other metrics. For example, the cost function 522 may be defined as a sum of squares of a composite metric, which is defined as a weighted sum of the image differences, the defocused image gradient, and the image log slope.

As described above, a gradient of the cost function 522 is defined in certain embodiments, and the gradient of the cost function 522 is used in a gradient optimization algorithm to minimize the cost function 522 by modifying one or more of primary mask features 406, first curved sub-resolution assist features 410a, and second sub-resolution assist features 410b. As described above, the features (406, 408, 410a, 410b) are modified in various ways according to respective embodiments. For example, modification operations include decreasing a width of one or more of the primary mask features 406 and the curved sub-resolution assist features 410 to increase a relative separation of neighboring features; dividing one or more of the primary mask features 406 and the curved sub-resolution assist features by removing a portion of one or more of the primary mask features 406 and the sub-resolution assist features 408, and removing one or more of the primary mask features 406 and the sub-resolution assist features 408.

In further embodiments, the computational lithography process 500 omits operations 528 associated with the inverse aerial image (i.e., generated based on the target aerial image 502) for a certain number of iterations, but then performs such operations 528, for example, to smooth out sharp features in the updated mask layout. As such, the computational lithography process 500 may be a hybrid process that performs certain operations based on an approximate aerial image (i.e., generated by an updated mask layout) or may perform operations based on an inverse aerial image (i.e., generated based on an inverse transformation from a target aerial image 400a). As described above, under certain circumstances, the approximate aerial image and the inverse aerial image are effectively Fourier transforms of one another. Thus, in certain embodiments, the computational lithography process 500 may perform optimization operations in “Fourier space” as well as in “physical space.” This perspective is reasonable considering the equivalence between a mathematical description based on a function in “physical space” and a description based on a corresponding function in “Fourier space.”

FIG. 7A is an example initial mask layout 700a including primary mask features 406 and sub-resolution assist features 408, and FIG. 7B is a further mask layout 700b including primary mask features 406 and curved sub-resolution assist features (410a, 410b), according to various embodiments. FIG. 7C is a depth-of-focus plot 700c that compares a first depth of focus 702a of the initial mask layout 700a of FIG. 7A to a second depth of focus 702b of the further mask layout 700b of FIG. 7B, according to various embodiments. The mask layout 700b may be generated by the computational lithography process 500 based on the initial mask layout 700a, as described above with reference to FIG. 5. As shown in FIG. 7C, the mask layout 700b has been optimized based on the image log shape which shows a more gradual distance dependence corresponding to less sharp features (e.g., having fewer high-spatial-frequency components). As described above, the image log slope can be defined with respect to “physical space” (i.e., features of an aerial image generated by a mask layout) or with respect to “Fourier space” (i.e., features of the actual mask layout and can be used to smooth out high-spatial-frequency features (i.e., sharp corners may be rounded as shown in FIG. 3). In some embodiments, the image log slope (or other metrics) may be defined with respect to both “physical space” and “Fourier space” and operations in “both spaces” may be performed to optimize a mask layout for a given application.

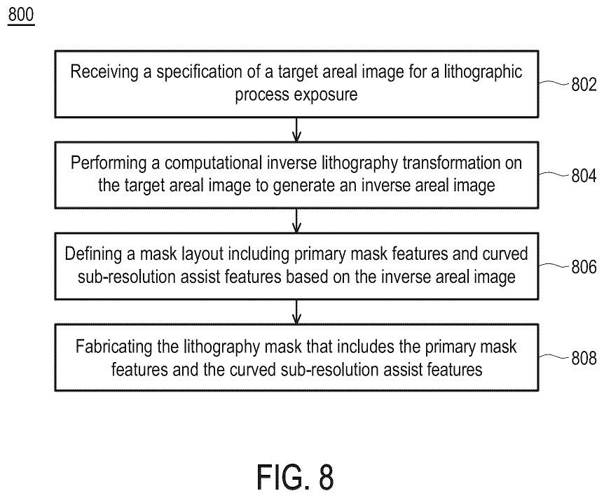

FIG. 8 is a flowchart illustrating operations of a method 800 of fabricating a lithography mask, according to various embodiments. In operation 802, the method 800 includes receiving a target aerial image (400a, 502) for a lithographic process exposure. In operation 804, the method 800 includes performing a computational inverse lithography transformation on the target aerial image (400a, 502) to generate an inverse aerial image 504. In operation 806, the method 800 includes defining a mask layout 520 including primary mask features 406 and curved sub-resolution assist features (408a, 408b) based on the inverse aerial image 504. In operation 808, the method 800 includes fabricating the lithography mask (400c, 700b) that includes the primary mask features 406 and the curved sub-resolution assist features (408a, 408b).

According to various embodiments, the method 800 further includes determining the primary mask features 406 and the curved sub-resolution assist features (408a, 408b) to correspond to a spatial distribution of intensities of the inverse aerial image 504 that exceed a first predetermined threshold. According to various embodiments, the method 800 further includes generating an inverse aerial image gradient 506 by determining differences between two or more inverse aerial images 504 computed at respective different focal distances, and determining the primary mask features 406 and the curved sub-resolution assist features (408a, 408b) based on the inverse aerial image gradient 506. According to various embodiments, the method 800 further includes determining an image log slope 510 based on the inverse aerial image 504, and determining the primary mask features 406 and the curved sub-resolution assist features (408a, 408b) based on the image log slope 510.

In defining the mask layout 520 according to operation 806, the method 800 further includes generating an inverse aerial image gradient 506 by determining differences between two or more inverse aerial images computed at respective different focal distances; determining an image log slope 510 based on the inverse aerial image 504; forming a weighted sum 512 of the inverse aerial image 504, the inverse aerial image gradient 506, and the image log slope 510; and determining the primary mask features 406 and the curved sub-resolution assist features (408a, 408b) to correspond to a spatial distribution of intensities of the weighted sum 512 that exceed a first predetermined threshold.

According to various embodiments, the method 800 further includes generating an approximate aerial image based on the mask layout 520 that includes the primary mask features 406 and the curved sub-resolution assist features (408a, 408b); determining image differences, which are spatially dependent numerical differences between the target aerial image (400a, 502) and the approximate aerial image; determining a defocused image gradient by computing aerial image differences between the approximate aerial image computed at two or more focal distances; determining an image log slope based on the approximate aerial image; determining a composite metric, which is a weighted sum 512 of the image differences, the defocused image gradient, and the image log slope 510; and defining a cost function 522 to be a sum of squares of the composite metric.

According to various embodiments, the method 800 further includes performing an iterative minimization procedure to reduce the cost function 522 by performing operations including: modifying one or more of the primary mask features 406 or the curved sub-resolution assist features (408a, 408b) to generate a candidate modified mask layout 520; determining a modified approximate aerial image based on the candidate modified mask layout 520; determining a modified cost function 522 based on the modified approximate aerial image; accepting the candidate modified mask layout 520 as an updated mask layout 520 when the modified cost function 522 is lower than the cost function 522 in a previous iteration; and rejecting the candidate modified mask layout 520 as the updated mask layout 520 when the modified cost function 522 is greater than the cost function 522 in the previous iteration.

According to various embodiments, the method 800 further includes performing the iterative minimization procedure until the cost function 522 is reduced below a second predetermined threshold or until a predetermined maximum number of iterations have been exceeded, and defining the output mask layout 526 as a most recently accepted candidate modified mask layout 520. According to various embodiments, the method 800 further includes computing a gradient of the cost function 522, which quantifies changes in the cost function 522 based on changing one or more of sizes and shapes of one or more of the primary mask features 406 and the curved sub-resolution assist features (408a, 408b); and performing the iterative minimization procedure using a gradient optimization algorithm based on the gradient of the cost function 522.

According to various embodiments, modifying one or more of the primary mask features 406 and the curved sub-resolution assist features (408a, 408b) according to the method 800 further includes performing one or more operations including: decreasing a width of one or more of the primary mask features 406 and the curved sub-resolution assist features (408a, 408b) to increase a relative separation of neighboring features; dividing one or more of the primary mask features 406 and the curved sub-resolution assist features (408a, 408b) by removing a portion of one or more of the primary mask features 406 and the curved sub-resolution assist features (408a, 408b); and removing one or more of the primary mask features 406 and the curved sub-resolution assist features (408a, 408b). According to the method 800, the operations of decreasing the width, dividing, and removing are performed such that the primary mask features 406 and the curved sub-resolution assist features (408a, 408b) satisfy one or more constraint rules.

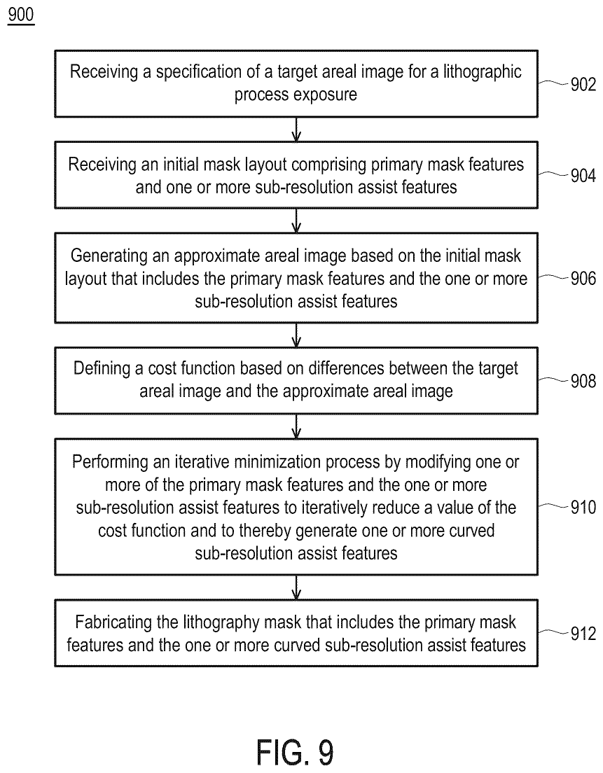

FIG. 9 is a flowchart illustrating operations of a method 800 of fabricating a lithography mask, according to various embodiments. In operation 902, the method 900 includes receiving a target aerial image (400a, 502) for a lithographic process exposure. In operation 904, the method 900 includes receiving an initial mask layout (400b, 600a, 700a) including primary mask features 406 and one or more sub-resolution assist features 408. In operation 906, the method 900 includes generating an approximate aerial image based on the initial mask layout (400b, 600a, 700a) that includes the primary mask features 406 and the one or more sub-resolution assist features 408. In operation 908, the method 900 includes defining a cost function 522 based on differences between the target aerial image (400a, 502) and the approximate aerial image.

In operation 910, the method 900 includes performing an iterative minimization process by modifying one or more of the primary mask features 406 and the one or more sub-resolution assist features 408 to iteratively reduce a value of the cost function 522 and to thereby generate one or more curved sub-resolution assist features (408a, 408b). In operation 912, the method 900 includes fabricating the lithography mask (400c, 700b) that includes the primary mask features 406 and the one or more curved sub-resolution assist features (408a, 408b).

According to various embodiments, the method 900 further includes defining the cost function 522 to be based on one or more of: image differences, which are spatially dependent numerical differences between the target aerial image (400a, 502) and the approximate aerial image; a defocused image gradient, which is determined by computing aerial image differences between the approximate aerial image computed at two or more focal distances; and an image log slope, determined based on the approximate aerial image. According to various embodiments, the method 900 further includes determining a composite metric, which is a weighted sum of the image differences, the defocused image gradient, and the image log slope; and defining the cost function 522 to be a sum of squares of the composite metric.

According to various embodiments, the method 900 further includes computing a gradient of the cost function 522, which quantifies changes in the cost function 522 based on changing one or more of sizes and shapes of one or more of the primary mask features 406 and curved sub-resolution assist features (408a, 408b); and performing the iterative minimization process using a gradient optimization algorithm based on the gradient of the cost function 522. According to various embodiments, the method 900 further includes computing the gradient of the cost function 522 to include variations associated with changing values of weight parameters in the weighted sum of the image differences, the defocused image gradient, and the image log slope that includes the composite metric. According to various embodiments, the method 900 further includes performing a computational inverse lithography transformation on the target aerial image (400a, 502) to generate an inverse aerial image 504, and defining the one or more curved sub-resolution assist features (408a, 408b) corresponding to a spatial distribution of intensities of the inverse aerial image 504 that exceed a first predetermined threshold.

According to various embodiments, in modifying one or more of the primary mask features 406 and sub-resolution assist features 408 according to operation 910, the method 900 further includes performing one or more operations including: decreasing a width of one or more of the primary mask features 406 and the sub-resolution assist features 408 to increase a relative separation of neighboring features; dividing one or more of the primary mask features 406 and the sub-resolution assist features 408 by removing a portion of one or more of the primary mask features 406 and the sub-resolution assist features 408; and removing one or more of the primary mask features 406 and the sub-resolution assist features 408. According to the method 900, the operations of decreasing the width, dividing, and removing are performed such that a spatial distribution of the primary mask features 406 and curved sub-resolution assist features (408a, 408b) satisfy one or more constraint rules.

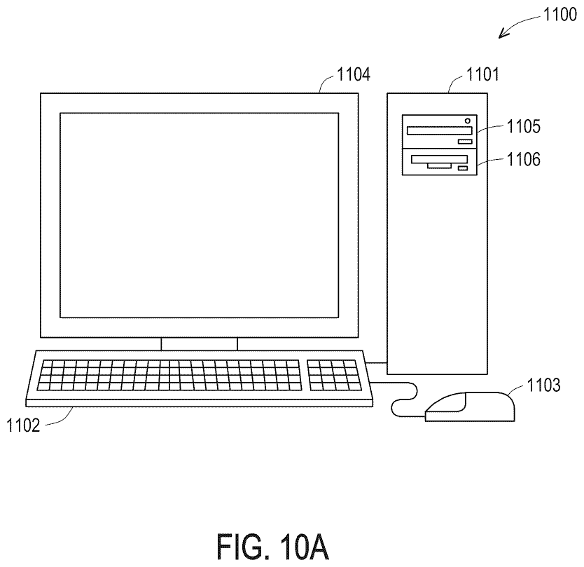

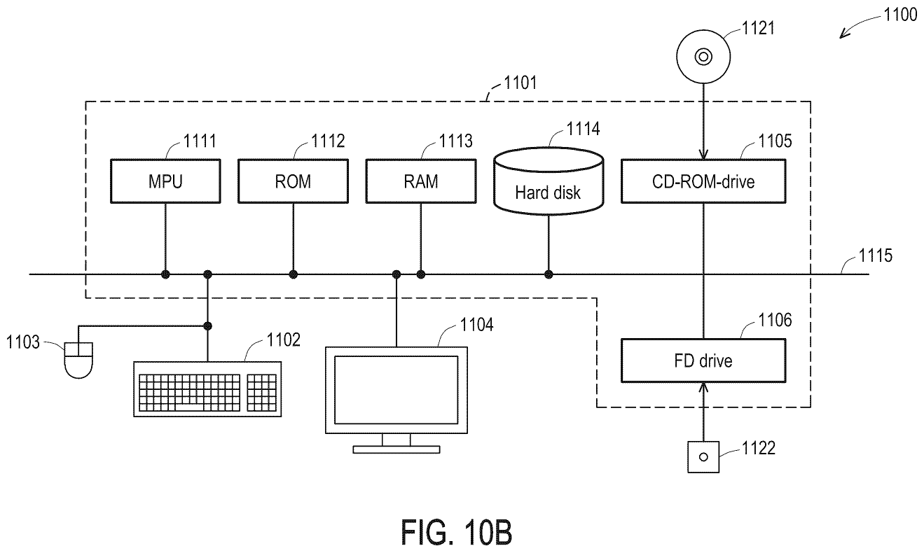

FIGS. 10A and 10B illustrate an apparatus 1100 configured to perform the methods of FIGS. 8 and 9, according to various embodiments. In some embodiments, the apparatus 1100 is an optical simulator and/or a mask data preparation apparatus 1100. FIG. 10A is a schematic view of a computer system that executes the processes of defining a mask layout according to one or more embodiments as described above. All of or a part of the processes, methods, and/or operations of the above-described embodiments can be realized using computer hardware and computer programs executed thereon. In FIG. 10A, a computer system 1100 is provided with a computer 1101 including an optical disk read-only memory (e.g., CD-ROM or DVD-ROM) drive 1105 and a magnetic disk drive 1106, a keyboard 1102, a mouse 1103, and a monitor 1104.

FIG. 10B is a diagram showing an internal configuration of the computer system 1100. The computer 1101 is provided with, in addition to the optical disk drive 1105 and the magnetic disk drive 1106, one or more processors 1111, such as a micro processing unit (MPU), a read-only memory (ROM) 1112 in which a program, such as a boot-up program is stored, a random access memory (RAM) 1113 that is connected to the MPU 1111 and in which a command of an application program is temporarily stored and a temporary storage area is provided, a hard disk 1114 in which an application program, a system program, and data are stored, and a bus 1115 that connects the MPU 1111, the ROM 1112, and the like. Note that the computer 1101 may include a network card (not shown) for providing a connection to a LAN.

Computer program instructions, configured to cause the computer system 1100 to execute the process for defining a mask layout in the foregoing embodiments are stored in a non-transitory computer-readable storage medium, such as an optical disk 1121 or a magnetic disk 1122. Such a storage medium is configured to be inserted into the optical disk drive 1105 or the magnetic disk drive 1106, and transmitted to the hard disk 1114. Alternatively, the program may be transmitted via a network (not shown) to the computer 1101 and stored in the hard disk 1114 (or other non-transitory computer-readable storage medium). At the time of execution, the program is loaded into the RAM 1113. The program may be loaded from the optical disk 1121 or the magnetic disk 1122, or directly from a network. The program does not necessarily need to include, for example, an operating system (OS) or a third-party program to cause the computer 1101 to execute the process for manufacturing the lithographic mask of a semiconductor device in the foregoing embodiments. The program may only include a command portion to call an appropriate function (module) in a controlled mode and obtain desired results.

Referring to all drawings and according to various embodiments of the present disclosure, a lithography mask (400c, 700b) is provided. The lithography mask (400c, 700b) includes primary mask features 406 and one or more curved sub-resolution assist features (408a, 408b). According to various embodiments, at least one of the one or more curved sub-resolution assist features (408a, 408b) includes a transmissive feature formed within a non-transmissive primary mask feature, or at least one of the one or more curved sub-resolution assist features (408a, 408b) includes a non-transmissive feature formed within a transmissive primary mask feature. According to various embodiments, the lithography mask (400c, 700b) further includes a first depth of focus 702a that is greater than a corresponding second depth of focus 702b of a corresponding lithography mask (400b, 700a) that does not include the one or more curved sub-resolution assist features (408a, 408b). According to various embodiments, the lithography mask (400c, 700b) further includes one or more additional curved sub-resolution assist features (408a, 408b) that have a non-uniform width.

Disclosed embodiments are advantageous by providing a method (800, 900) of fabricating a lithography mask (400c, 700b) based on a computational lithography process 500 that optimizes the lithography mask (400c, 700b) to have improved depth of focus (702a, 702b) or other metrics. The resulting lithography mask (400c, 700b) includes primary mask features 406 and curved sub-resolution assist features (410a, 410b) that satisfy various constraints of mask printability, depth of focus of an aerial image generated by the lithography mask (400c, 700b), and design constraints of the aerial image. The method includes performing an iterative optimization algorithm 500 based on a gradient of a cost function 522 that is based on one or more metrics including differences between a projected aerial image and a target image 502, a defocused image gradient, and an image log slope of the projected aerial image.

According to various embodiments, a method of fabricating a lithography mask is provided. The method includes receiving a target aerial image for a lithographic process exposure; performing a computational inverse lithography transformation on the target aerial image to generate an inverse aerial image; defining a mask layout including primary mask features and curved sub-resolution assist features based on the inverse aerial image; and fabricating the lithography mask that includes the primary mask features and the curved sub-resolution assist features.

According to various embodiments, the method further includes determining the primary mask features and the curved sub-resolution assist features to correspond to a spatial distribution of intensities of the inverse aerial image that exceed a first threshold. According to various embodiments, the method further includes generating an inverse aerial image gradient by determining differences between two or more inverse aerial images computed at respective different focal distances, and determining the primary mask features and the curved sub-resolution assist features based on the inverse aerial image gradient. According to various embodiments, the method further includes determining an image log slope based on the inverse aerial image, and determining the primary mask features and the curved sub-resolution assist features based on the image log slope.

In defining the mask layout, according to various embodiments, the method further includes generating an inverse aerial image gradient by determining differences between two or more inverse aerial images computed at respective different focal distances; determining an image log slope based on the inverse aerial image; forming a weighted sum of the inverse aerial image, the inverse aerial image gradient, and the image log slope; and determining the primary mask features and the curved sub-resolution assist features to correspond to a spatial distribution of intensities of the weighted sum that exceed a first threshold.

According to various embodiments, the method further includes generating an approximate aerial image based on the mask layout that includes the primary mask features and the curved sub-resolution assist features; determining image differences, which are spatially dependent numerical differences between the target aerial image and the approximate aerial image; determining a defocused image gradient by computing aerial image differences between the approximate aerial image computed at two or more focal distances; determining an image log slope based on the approximate aerial image; determining a composite metric, which is a weighted sum of the image differences, the defocused image gradient, and the image log slope; and defining a cost function to be a sum of squares of the composite metric.

According to various embodiments, the method further includes performing an iterative minimization procedure to reduce the cost function by performing operations including: modifying one or more of the primary mask features or the curved sub-resolution assist features to generate a candidate modified mask layout; determining a modified approximate aerial image based on the candidate modified mask layout; determining a modified cost function based on the modified approximate aerial image; accepting the candidate modified mask layout as an updated mask layout when the modified cost function is lower than the cost function in a previous iteration; and rejecting the candidate modified mask layout as the updated mask layout when the modified cost function is greater than the cost function in the previous iteration.

According to various embodiments, the method further includes performing the iterative minimization procedure until the cost function is reduced below a second threshold or until a maximum number of iterations have been exceeded, and defining the output mask layout as a most recently accepted candidate modified mask layout. According to various embodiments, the method further includes computing a gradient of the cost function, which quantifies changes in the cost function based on changing one or more of sizes and shapes of one or more of the primary mask features and the curved sub-resolution assist features; and performing the iterative minimization procedure using a gradient optimization algorithm based on the gradient of the cost function.

In modifying one or more of the primary mask features and the curved sub-resolution assist features, according to various embodiments, the method further includes performing one or more operations including: decreasing a width of one or more of the primary mask features and the curved sub-resolution assist features to increase a relative separation of neighboring features; dividing one or more of the primary mask features and the curved sub-resolution assist features by removing a portion of one or more of the primary mask features and the curved sub-resolution assist features; and removing one or more of the primary mask features and the curved sub-resolution assist features. According to the method, the operations of decreasing the width, dividing, and removing are performed such that the primary mask features and the curved sub-resolution assist features satisfy one or more constraint rules.

According to various embodiments, a further method of fabricating a lithography mask is provided. The method includes receiving a target aerial image for a lithographic process exposure; receiving an initial mask layout including primary mask features and one or more sub-resolution assist features; generating an approximate aerial image based on the initial mask layout that includes the primary mask features and the one or more sub-resolution assist features; defining a cost function based on differences between the target aerial image and the approximate aerial image; performing an iterative minimization process by modifying one or more of the primary mask features and the one or more sub-resolution assist features to iteratively reduce a value of the cost function and to thereby generate one or more curved sub-resolution assist features; and fabricating the lithography mask that includes the primary mask features and the one or more curved sub-resolution assist features.

According to various embodiments, the method further includes defining the cost function to be based on one or more of: image differences, which are spatially dependent numerical differences between the target aerial image and the approximate aerial image; a defocused image gradient, which is determined by computing aerial image differences between the approximate aerial image computed at two or more focal distances; and an image log slope, determined based on the approximate aerial image. According to various embodiments, the method further includes determining a composite metric, which is a weighted sum of the image differences, the defocused image gradient, and the image log slope; and defining the cost function to be a sum of squares of the composite metric.

According to various embodiments, the method further includes computing a gradient of the cost function, which quantifies changes in the cost function based on changing one or more of sizes and shapes of one or more of the primary mask features and curved sub-resolution assist features; and performing the iterative minimization process using a gradient optimization algorithm based on the gradient of the cost function. According to various embodiments, the method further includes computing the gradient of the cost function to include variations associated with changing values of weight parameters in the weighted sum of the image differences, the defocused image gradient, and the image log slope that includes the composite metric. According to various embodiments, the method further includes performing a computational inverse lithography transformation on the target aerial image to generate an inverse aerial image, and defining the one or more curved sub-resolution assist features corresponding to a spatial distribution of intensities of the inverse aerial image that exceed a first threshold.

According to various embodiments, in modifying one or more of the primary mask features and sub-resolution assist features, the method further includes performing one or more operations including: decreasing a width of one or more of the primary mask features and the sub-resolution assist features to increase a relative separation of neighboring features; dividing one or more of the primary mask features and the sub-resolution assist features by removing a portion of one or more of the primary mask features and the sub-resolution assist features; and removing one or more of the primary mask features and the sub-resolution assist features. According to the method, the operations of decreasing the width, dividing, and removing are performed such that a spatial distribution of the primary mask features and curved sub-resolution assist features satisfy one or more constraint rules.

According to various embodiments, a non-transitory computer-readable storage medium is provided that includes computer program instructions stored thereon that, when executed by a processor, cause the processor to perform operations of a method of fabricating a lithography mask. According to various embodiments, the operations include receiving a target aerial image for a lithographic process exposure; performing a computational inverse lithography transformation on the target aerial image to generate an inverse aerial image; defining a mask layout including primary mask features and curved sub-resolution assist features based on the inverse aerial image; and fabricating the lithography mask that includes the primary mask features and the curved sub-resolution assist features.

According to various embodiments, the non-transitory computer-readable storage medium includes further computer program instructions that, when executed by the processor, cause the processor to perform further operations including generating an inverse aerial image gradient by determining differences between two or more inverse aerial images computed at respective different focal distances; determining an image log slope based on the inverse aerial image; forming a weighted sum of the inverse aerial image, the inverse aerial image gradient, and the image log slope; and determining the primary mask features and the curved sub-resolution assist features to correspond to a spatial distribution of intensities of the weighted sum that exceed a first predetermined threshold.

According to various embodiments, the non-transitory computer-readable storage medium includes further computer program instructions that, when executed by the processor, cause the processor to perform further operations including generating an approximate aerial image based on the mask layout that includes the primary mask features and the curved sub-resolution assist features; determining image differences, which are spatially dependent numerical differences between the target aerial image and the approximate aerial image; determining a defocused image gradient by computing aerial image differences between the approximate aerial image computed at two or more focal distances; determining an image log slope based on the approximate aerial image; determining a composite metric, which is a weighted sum of the image differences, the defocused image gradient, and the image log slope; and defining a cost function to be a sum of squares of the composite metric.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of fabricating a lithography mask, comprising:
receiving a target aerial image for a lithographic process exposure;
performing a computational inverse lithography transformation on the target aerial image to generate an inverse aerial image;
defining a mask layout comprising primary mask features and curved sub-resolution assist features based on the inverse aerial image; and
fabricating the lithography mask that includes the primary mask features and the curved sub-resolution assist features.

2. The method of claim 1, wherein defining the mask layout further comprises:
determining the primary mask features and the curved sub-resolution assist features to correspond to a spatial distribution of intensities of the inverse aerial image that exceed a first threshold.

3. The method of claim 1, further comprising:
generating an inverse aerial image gradient by determining differences between two or more inverse aerial images computed at respective different focal distances; and
determining the primary mask features and the curved sub-resolution assist features based on the inverse aerial image gradient.

4. The method of claim 1, further comprising:
determining an image log slope based on the inverse aerial image; and
determining the primary mask features and the curved sub-resolution assist features based on the image log slope.

5. The method of claim 1, wherein defining the mask layout further comprises:
generating an inverse aerial image gradient by determining differences between two or more inverse aerial images computed at respective different focal distances;
determining an image log slope based on the inverse aerial image;
forming a weighted sum of the inverse aerial image, the inverse aerial image gradient, and the image log slope; and
determining the primary mask features and the curved sub-resolution assist features to correspond to a spatial distribution of intensities of the weighted sum that exceed a first threshold.

6. The method of claim 1, further comprising:
generating an approximate aerial image based on the mask layout that includes the primary mask features and the curved sub-resolution assist features;
determining image differences, which are spatially dependent numerical differences between the target aerial image and the approximate aerial image;
determining a defocused image gradient by computing aerial image differences between the approximate aerial image computed at two or more focal distances;
determining an image log slope based on the approximate aerial image;
determining a composite metric, which is a weighted sum of the image differences, the defocused image gradient, and the image log slope; and
defining a cost function to be a sum of squares of the composite metric.

7. The method of claim 6, further comprising performing an iterative minimization procedure to reduce the cost function by performing operations comprising:
modifying one or more of the primary mask features or the curved sub-resolution assist features to generate a candidate modified mask layout;
determining a modified approximate aerial image based on the candidate modified mask layout;
determining a modified cost function based on the modified approximate aerial image;
accepting the candidate modified mask layout as an updated mask layout when the modified cost function is lower than the cost function in a previous iteration; and
rejecting the candidate modified mask layout as the updated mask layout when the modified cost function is greater than the cost function in the previous iteration.

8. The method of claim 7, further comprising:
performing the iterative minimization procedure until the cost function is reduced below a second threshold or until a maximum number of iteration has been exceeded; and
defining the mask layout as a most recently accepted candidate modified mask layout.

9. The method of claim 7, further comprising:
computing a gradient of the cost function, which quantifies changes in the cost function based on changing one or more of sizes and shapes of one or more of the primary mask features and the curved sub-resolution assist features; and
performing the iterative minimization procedure using a gradient optimization algorithm based on the gradient of the cost function.

10. The method of claim 2, wherein modifying one or more of the primary mask features and the curved sub-resolution assist features further comprises performing one or more of operations comprising:
decreasing a width of one or more of the primary mask features and the curved sub-resolution assist features to increase a relative separation of neighboring features;
dividing one or more of the primary mask features and the curved sub-resolution assist features by removing a portion of one or more of the primary mask features and the curved sub-resolution assist features; and
removing one or more of the primary mask features and the curved sub-resolution assist features,
wherein the operations of decreasing the width, dividing, and removing are performed such that the primary mask features and the curved sub-resolution assist features satisfy one or more constraint rules.

11. A method of fabricating a lithography mask, comprising:
receiving a target aerial image for a lithographic process exposure;
receiving an initial mask layout comprising primary mask features and one or more sub-resolution assist features;
generating an approximate aerial image based on the initial mask layout that includes the primary mask features and the one or more sub-resolution assist features;
defining a cost function based on differences between the target aerial image and the approximate aerial image;
performing an iterative minimization process by modifying one or more of the primary mask features and the one or more sub-resolution assist features to iteratively reduce a value of the cost function and to thereby generate one or more curved sub-resolution assist features; and
fabricating the lithography mask that includes the primary mask features and the one or more curved sub-resolution assist features.

12. The method of claim 11, further comprising defining the cost function to be based on one or more of:
image differences, which are spatially dependent numerical differences between the target aerial image and the approximate aerial image;
a defocused image gradient, which is determined by computing aerial image differences between the approximate aerial image computed at two or more focal distances; and
an image log slope, determined based on the approximate aerial image.

13. The method of claim 12, further comprising:
determining a composite metric, which is a weighted sum of the image differences, the defocused image gradient, and the image log slope; and
defining the cost function to be a sum of squares of the composite metric.

14. The method of claim 13, further comprising:
computing a gradient of the cost function, which quantifies changes in the cost function based on changing one or more of sizes and shapes of one or more of the primary mask features and curved sub-resolution assist features; and
performing the iterative minimization process using a gradient optimization algorithm based on the gradient of the cost function.

15. The method of claim 14, further comprising:
computing the gradient of the cost function to include variations associated with changing values of weight parameters in the weighted sum of the image differences, the defocused image gradient, and the image log slope that comprises the composite metric.

16. The method of claim 11, further comprising:
performing a computational inverse lithography transformation on the target aerial image to generate an inverse aerial image; and
defining the one or more curved sub-resolution assist features corresponding to a spatial distribution of intensities of the inverse aerial image that exceed a first threshold.

17. The method of claim 11, wherein modifying one or more of the primary mask features and the sub-resolution assist features further comprises performing one or more operations comprising:
decreasing a width of one or more of the primary mask features and the sub-resolution assist features to increase a relative separation of neighboring features;
dividing one or more of the primary mask features and the sub-resolution assist features by removing a portion of one or more of the primary mask features and the sub-resolution assist features; and
removing one or more of the primary mask features and the sub-resolution assist features,
wherein decreasing the width, dividing, and removing are performed such that a spatial distribution of the primary mask features and curved sub-resolution assist features satisfy one or more constraint rules.

18. A non-transitory computer-readable storage medium comprising computer program instructions stored thereon that, when executed by a processor, cause the processor to perform operations comprising:
receiving a target aerial image for a lithographic process exposure;
performing a computational inverse lithography transformation on the target aerial image to generate an inverse aerial image;
defining a mask layout comprising primary mask features and curved sub-resolution assist features based on the inverse aerial image; and
fabricating a lithography mask that includes the primary mask features and the curved sub-resolution assist features.

19. The non-transitory computer-readable storage medium of claim 18, comprising further computer program instructions that, when executed by the processor, cause the processor to perform further operations comprising:
generating an inverse aerial image gradient by determining differences between two or more inverse aerial images computed at respective different focal distances;
determining an image log slope based on the inverse aerial image;
forming a weighted sum of the inverse aerial image, the inverse aerial image gradient, and the image log slope; and
determining the primary mask features and the curved sub-resolution assist features to correspond to a spatial distribution of intensities of the weighted sum that exceed a first threshold.

20. The non-transitory computer-readable storage medium of claim 18, comprising further computer program instructions that, when executed by the processor, cause the processor to perform further operations comprising:
generating an approximate aerial image based on the mask layout that includes the primary mask features and the curved sub-resolution assist features;
determining image differences, which are spatially dependent numerical differences between the target aerial image and the approximate aerial image;
determining a defocused image gradient by computing aerial image differences between the approximate aerial image computed at two or more focal distances;
determining an image log slope based on the approximate aerial image;
determining a composite metric, which is a weighted sum of the image differences, the defocused image gradient, and the image log slope; and
defining a cost function to be a sum of squares of the composite metric.
